(19) United States
(12) Patent Application Publication
(10) Pub. No.: US 2025/0217051 A1
(43) Pub. Date: Jul. 3, 2025

(54) MERGED MEMORY COMMANDS FOR IMPROVED BUS UTILIZATION IN VOLATILE MEMORY

(71) Applicant: QUALCOMM Incorporated, San Diego, CA (US)

(72) Inventors: Madhukar Reddy N, Hyderabad (IN); Amulya Srinivasan Margasahayam, Bangalore (IN); Vasantha Kumar Bandur Puttappa, Bangalore (IN); Abhay Raj, Lucknow (IN); Saurabh Sethi, Mohali (IN)

(21) Appl. No.: 18/398,396

(22) Filed: Dec. 28, 2023

(51) Int. Cl. G06F 3/06

(52) U.S. Cl. CPC G06F 3/0625; G06F 3/0659; G06F 3/0673

(57) ABSTRACT

This disclosure provides systems, methods, and devices for memory systems that support merged memory commands for improved bus utilization in volatile memory. In a first aspect, a method of performing operations on a memory module includes receiving, from a host device by a memory controller coupled to a memory module through a first channel and configured to access data stored in the memory module through the first channel, a merged command for performing at least a precharge operation, a refresh operation, and an activate operation on one or more rows of the memory module and performing the precharge operation, the refresh operation, and the activate operation in accordance with receipt of the merged command. Other aspects and features are also claimed and described.

### TECHNICAL FIELD

Aspects of the present disclosure relate generally to computer information systems, and more particularly, to memory systems for storing data. Some features may enable and provide improved memory capabilities for merged memory commands for improved bus utilization, reduced power usage, and enhanced performance.

### INTRODUCTION

A computing device (e.g., a laptop, a mobile phone, etc.) may include one or several processors to perform various computing functions, such as telephony, wireless data access, and camera/video function, etc. A memory system is an important component of the computing device. The processors may be coupled to the memory system to perform the aforementioned computing functions. For example, the processors may fetch instructions from the memory system to perform the computing functions and/or to store within the memory system temporary data involved in performing these computing functions.

Memory systems may make use of memory cells that are volatile in nature. Volatile memory cells retain information for short periods of time, such as fractions of a second. One example operation that may be performed on memory cells is a refresh operation. A refresh operation may be performed with volatile memory cells to maintain the information for longer periods of time. In an example volatile memory cell storing information as an electrical charge, the electrical charge decays over a fraction of a second. Before the charge decays beyond the point of lost information, the memory cell may be refreshed to extend the period of time that the memory cell retains the information. In some cases the refresh may be repeatedly performed to extend the period of storage of the information indefinitely, or as long as electricity is supplied to the circuit. This refresh operation consumes power, which impacts the operation of devices operating from limited power sources, such as with mobile devices operating from battery power. Other examples of operations that may be performed on memory cells are activate operations, to prepare the memory cells to be read from or written to, and precharge operations to deactivate memory cells after an operation has been performed on them.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

In some aspects, a single command may be used to instruct a memory device, such as a memory controller connected to a memory module, to perform a precharge operation, a refresh operation, and an activate operation on one or more rows of one or more banks of the memory module. For example, a host device may generate and transmit and a memory controller may receive a command for performing a precharge operation, a refresh operation, and an activate operation. The memory controller may then perform the precharge operation, the refresh operation, and the activate operation on one or more rows of one or more memory banks of the memory module connected to the memory controller. The command may, for example, be transmitted via a command bus between the host device and the memory controller. As one example, the command may be (1) a merged precharge command that also includes commands to perform a refresh operation and an activate operation, (2) a merged refresh command that also includes commands to perform a precharge operation and an activate operation, (3) a read command that also includes commands to perform a precharge operation, a refresh operation, and an activate operation, or (4) a write command that also includes commands to perform a precharge operation, a refresh operation, and an activate operation. Use of a merged command, as described herein, may reduce congestion on a command bus in a dynamic random access memory (DRAM) system, allowing for more efficient usage of command bus bandwidth. Merged command, as used herein, may refer to merged memory commands. For example, merging precharge, refresh, and activate commands into a single command transmitted via the command bus may reduce a number of commands sent via a command bus to perform such operations, freeing command bus bandwidth for other uses.

These aspects may be embodied as one or more commands transmitted from a host to a memory system. The commands transmitted by the host may include commands to read capabilities from the memory system, set configurations in the memory system, read data at one or more specified addresses from the memory system, and/or write data at one or more specified addresses to the memory system.

An apparatus in accordance with at least one embodiment includes a memory system configured to communicate with a host. The memory system includes a memory array configured to store data. The memory system may include a memory controller configured to provide the data stored in the memory array to the host for further processing by the processor or other components of the host. The memory controller may also be configured to receive data from the host for storage in the memory array. In some embodiments, the memory array may be a plurality of volatile memory cells organized in rows and columns, such as in a dynamic random access memory (DRAM) or static random access memory (SRAM).

An apparatus in accordance with at least one other embodiment includes a host device with a memory controller configured to communicate with a memory system to receive data stored in the memory array and/or to store data in the memory array. The host device may be, for example, a user equipment (UE) device such as a cellular phone, a tablet computing device, a personal computer, a server, a smart watch, or an internet of things (IoT) device.

In one aspect of the disclosure, a method includes receiving, from a host device by a memory controller, wherein the memory controller is coupled to a memory module through a first channel and is configured to access data stored in the memory module through the first channel, a merged command for performing at least a precharge operation, a refresh operation, and an activate operation on one or more rows of the memory module and performing the precharge operation, the refresh operation, and the activate operation in accordance with receipt of the merged command.

In an additional aspect of the disclosure, an apparatus includes at least one processor and a memory coupled to the at least one processor. The at least one processor is configured to perform operations comprising receiving, from a host device, a merged command for performing at least a precharge operation, a refresh operation, and an activate operation on one or more rows of the memory module and performing the precharge operation, the refresh operation, and the activate operation in accordance with receipt of the merged command. The processor may be a processor, controller, or other logic circuitry in a host. The processor may alternatively be a controller embedded in a memory device. For example, the processor may be a memory controller coupled to a memory module through a first channel and configured to access data stored in the memory module through the first channel.

In an additional aspect of the disclosure, a method includes generating, by a host device configured to communicate with a memory module via a channel, a merged command for performing at least a precharge operation, a refresh operation, and an activate operation on one or more rows of the memory module and transmitting the merged command to the memory module.

In an additional aspect of the disclosure, an apparatus includes at least one processor and a memory coupled to the at least one processor. The at least one processor is configured to perform operations comprising generating a merged command for performing at least a precharge operation, a refresh operation, and an activate operation on one or more rows of the memory module and transmitting the merged command to the memory module. The processor may be a processor, controller, or other logic circuitry in a host. For example, the apparatus may include a host device configured to communicate with a memory module through a channel. The host device may include a memory controller coupled to the channel and configured to perform operations described herein. The processor may alternatively be a controller embedded in a memory device. For example, the processor may be a memory controller coupled to a memory module through a first channel and configured to access data stored in the memory module through the first channel.

In an additional aspect of the disclosure, an apparatus, such as a wireless device, includes at least one processor and a memory coupled to the at least one processor. The at least one processor is configured to communicate with the memory system through a memory controller coupled to a channel that couples the processor to the memory system. The processor may be a processor, controller, or other logic circuitry in a host.

In an additional aspect of the disclosure, a non-transitory computer-readable medium stores instructions that, when executed by a processor, cause the processor to perform operations described herein regarding aspects of the disclosure.

Memory systems in the present disclosure may be embedded within a processor on a semiconductor die or be part of a different semiconductor die. The memory systems may be of various kinds. For example, the memory may be static random access memory (SRAM), dynamic random access memory (DRAM), magnetic random access memory (MRAM), NAND flash, or NOR flash, etc.

Methods and apparatuses are presented in the present disclosure by way of non-limiting examples of Low-Power Double Data Rate (LPDDR) Synchronous Dynamic Random Access Memory (SDRAM). For example, the LPDDR memory operating in accordance with LPDDR specification promulgated by Joint Electronic Device Engineering Council (JEDEC). One such LPDDR specification may be LPDDR5. Another such LPDDR specification may be LPDDR6.

Other aspects, features, and implementations will become apparent to those of ordinary skill in the art, upon reviewing the following description of specific, exemplary aspects in conjunction with the accompanying figures. While features may be discussed relative to certain aspects and figures below, various aspects may include one or more of the advantageous features discussed herein. In other words, while one or more aspects may be discussed as having certain advantageous features, one or more of such features may also be used in accordance with the various aspects. In similar fashion, while exemplary aspects may be discussed below as device, system, or method aspects, the exemplary aspects may be implemented in various devices, systems, and methods.

The methods may be embedded in a computer-readable medium as computer program code comprising instructions that cause a processor to perform the steps of the method. In some embodiments, the processor may be part of a mobile device including a first network adaptor configured to transmit data, such as images or videos in a recording or as streaming data, over a first network connection of a plurality of network connections. The processor may be coupled to the first network adaptor and a memory for storing data to support the processing and communications operations performed by the processor. The network adaptor may support communication over a wireless communications network such as a 5G NR communication network. The processor may cause the transmission of data stored in memory over the wireless communication network.

The foregoing has outlined, rather broadly, the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 shows a block diagram of an example computing system incorporating a host, memory system, and channels coupling the host and the memory system according to one or more aspects of the disclosure.

FIG. 2 shows a block diagram of an example computing system incorporating a host, memory system, and channels coupling the host and the memory system with another implementation of the channels according to one or more aspects of the disclosure.

FIG. 3A and FIG. 3B illustrate waveforms for transfer of data through an example channel in a write operation in accordance with certain aspects of the present disclosure.

FIG. 4A and FIG. 4B illustrate waveforms for transfer of data through an example channel in a read operation in accordance with certain aspects of the present disclosure.

FIG. 5A is an example flow diagram of example memory commands in accordance with certain aspects of the present disclosure.

FIG. 5B is an example flow diagram of example merged memory commands in accordance with certain aspects of the present disclosure.

FIG. 5C is an example flow diagram of example merged memory commands in accordance with certain aspects of the present disclosure.

FIG. 5D is an example flow diagram of example merged memory commands in accordance with certain aspects of the present disclosure.

FIG. 6A is a chart of bits of an example read command in accordance with certain aspects of the present disclosure.

FIG. 6B is a chart of bit values of a read command and corresponding operations to be performed in response to the read command in accordance with certain aspects of the present disclosure.

FIG. 7A is a chart of bits of an example precharge command in accordance with certain aspects of the present disclosure.

FIG. 7B is a chart of bit values of a precharge command and corresponding precharge command formats in accordance with certain aspects of the present disclosure.

FIG. 8A is a chart of bits of an example refresh command in accordance with certain aspects of the present disclosure.

FIG. 8B is a chart of bit values of a refresh command and corresponding refresh command formats in accordance with certain aspects of the present disclosure.

FIG. 8C is a chart of bit values of a refresh command and corresponding refresh command formats in accordance with certain aspects of the present disclosure.

FIG. 9 is flow chart illustrating a method for merged memory command receipt and execution in accordance with certain aspects of the present disclosure.

FIG. 10 is a flow chart illustrating a method for merged memory command generation and transmission in accordance with certain aspects of the present disclosure.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

The present disclosure provides systems, apparatus, methods, and computer-readable media that support data processing, including techniques for merged memory commands for improved bus utilization in volatile memory. For example, precharge, refresh, and/or activate commands for one or more rows of one or more memory banks of a device may be merged into a single command, to form a merged memory command, transmitted via a command bus from a host device to a memory system. A merged memory command may be a single command for performing multiple operations by a memory module and/or controller. As one particular example, the single command may be a command with a precharge command format or a refresh command format and may include an indication that the memory system should perform a precharge operation, an activate operation, and/or a refresh operation on one or more rows of one or more banks of the memory system. As another example, the single command may be a command with a write format and may include an indication that the memory system should perform a write operation, a precharge operation, an activate operation, and/or a refresh operation on one or more rows of one or more banks of the memory system. As another example, the single command may be a command with a read format and may include an indication that the memory system should perform a read operation, a precharge operation, an activate operation, and/or a refresh operation on one or more rows of one or more banks of the memory system. In some aspects, the command may further specify one or more rows of one or more banks to which the operations should be applied.

Particular implementations of the subject matter described in this disclosure may be implemented to realize one or more of the following potential advantages or benefits. In some aspects, the present disclosure provides merged precharge, refresh, and/or activate commands for transmission on a command bus between a host device and a memory system, such as between a memory controller and a memory system. Such merging may reduce congestion of the command bus, particularly in the context of dynamic random access memory (DRAM). For example, in DRAM, to precharge open pages, or rows, of a memory module, a precharge command may be sent before a refresh command, and a subsequent activate command may be sent following the refresh command to activate a same row again when there are multiple pending page hits for the row. Merging of precharge, refresh, and activate commands, and, in some aspects, read or write commands, may reduce a number of commands transmitted via a command bus, thereby reducing congestion of the command bus and freeing bus bandwidth for transmission of other commands. Merged precharge, refresh, and activate commands may be particularly useful for reducing command bus congestion in the context of precharge, refresh, and activate operations performed on frequently accessed pages or rows of a memory module. Such reductions in congestion may lead to enhanced memory performance and reduced power consumption by memory systems.

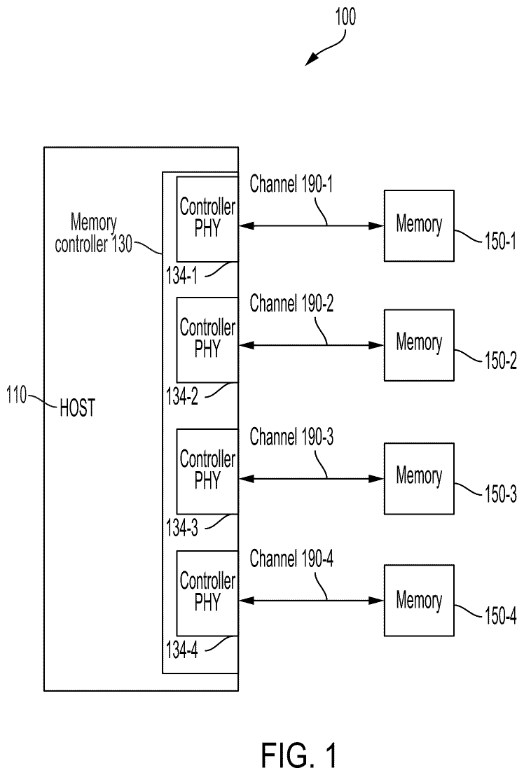

An example memory device that may incorporate aspects of this disclosure, including merged memory commands for improved bus utilization in volatile memory, is shown in FIG. 1. FIG. 1 illustrates an apparatus 100 incorporating a host 110, memories 150, and channels 190 coupling the host 110 and the memories 150. The apparatus 100 may be, for example, a device among computing systems (e.g., servers, datacenters, desktop computers), mobile computing device (e.g., laptops, cell phones, vehicles, etc.), Internet of Things devices, virtual reality (VR) systems, augmented reality (AR) systems, automobile systems (e.g., driver assistance systems, autonomous driving systems), image capture devices (e.g., stand-alone digital cameras or digital video camcorders, camera-equipped wireless communication device handsets, such as mobile telephones, cellular or satellite radio telephones, personal digital assistants (PDAs), panels or tablets, gaming devices, computing devices such as webcams, video surveillance cameras, or other devices with digital imaging or video capabilities), and/or multimedia systems (e.g., televisions, disc players, streaming devices,).

The host 110 may include at least one processor, such as central processing unit (CPU), graphic processing unit (GPU), digital signal processor (DSP), multimedia engine, and/or neural processing unit (NPU). The host 110 may be configured to couple and to communicate to the memories 150 (e.g., memories 150-1 to 150-4), via channels 190 (e.g., channels 190-1 to 190-4), in performing the computing functions, such as one of data processing, data communication, graphic display, camera, AR or VR rendering, image processing, neural processing, etc. For example, the memories 150-1 to 150-4 may store instructions or data for the host to perform the computing functions.

The host 110 may include a memory controller 130, which may include controller PHY modules 134-1 to 134-4. Each of the controller PHY modules 134-1 to 134-4 may be coupled to a respective one of the memories 150-1 to 150-4 via respective channels 190-1 to 190-4. For case of reference, read and write are referenced from a perspective of the host 110. For example, in a read operation, the host 110 may receive via one or more of the channels 190-1-190-4 data stored from one or more of the memories 150-1 to 150-4. In a write operation, the host 110 may provide via one or more of the channels 190-1-190-4 data to be written into one or more of the memories 150-1-150-4 for storage. The memory controller 130 may be configured to control various aspects, such as logic layers, of communications to and from the memories 150-1-150-4. The controller PHY modules 134-1-134-4 may be configured to control electrical characteristics (e.g., voltage levels, phase, delays, frequencies, etc.) of signals provided or received on the channels 190-1-190-4, respectively.

In some examples, the memories 150-1-150-4 may be LPDDR DRAM (e.g., LPDDR5, LPDDR6). In some examples, the memories 150-1-150-4 may be different kinds of memory, such as one LPDDR5, one LPDDR6, one Flash memory, and one SRAM, respectively. The host 110, the memories 150-1-150-4, and/or the channels 190-1-190-4 may operate according to an LPDDR (e.g., LPDDR5, LPDDR6) specification. In some examples, each of the channels 190-1-190-4 may include 16 bits of data (e.g., 16 DQs). In some examples, each of the channels 190-1-190-4 may operate on 32 bits of data (e.g., 32 DQs). In FIG. 1, four channels are shown, however the apparatus 100 may include more or less channels, such as 8 or 16 channels.

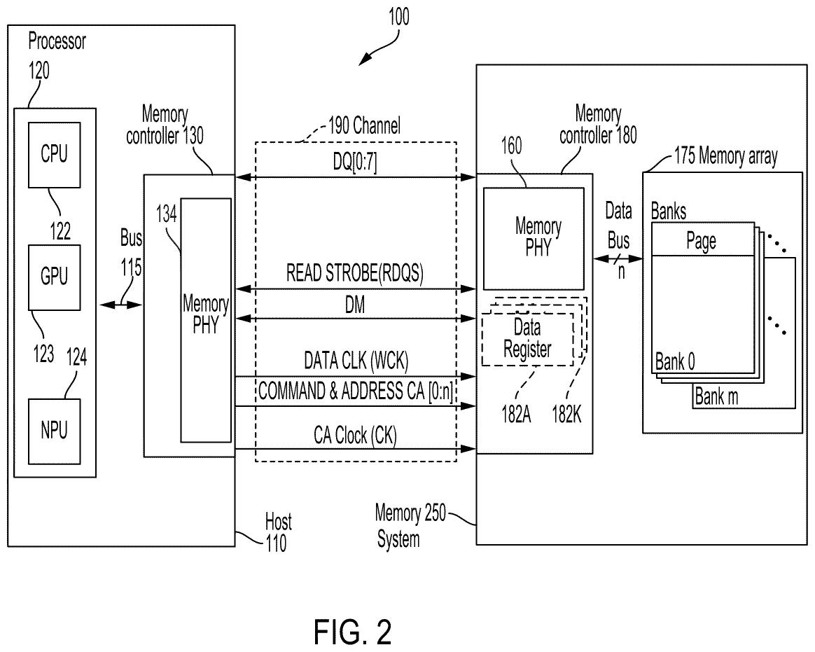

Additional details of an aspect of the embodiment of the apparatus 100 for providing access to a memory system (such as one of memories 150-1-150-4 including logic and control circuit) are shown in FIG. 2. FIG. 2 illustrates a configuration of the host 110, a memory system 250, and the channel 190 of FIG. 1. The channel 190 between host 110 and the memory system 250 may include a plurality of connections, some of which carry data (e.g., user data or application data) and some of which carry non-data (e.g., addresses and other signaling information). For example, non-data connections in channel 190 may include a data clock (e.g., WCK) used in providing data to the respective memory system 250 and a read data strobe (e.g., RDQS) used in receiving data from the respective memory system 250, on a per byte basis. The channel 190 may further include a data mask (e.g., DM, sometimes referred to as data mask inversion DMI to indicate multiple functions performed by the signal connection) signaling used to mask certain part of data in a write operation. The channel 190 may further include command and address (e.g., CA[0:n]) and associated CA clock to provide commands (e.g., read or write commands) to the memory system 250. For example, the CA[0:n] and/or CA Clock of the channel 190 may be a command bus for transmission of commands from the memory controller 130 to the memory system 250, as descried herein.

The host 110 may include at least one processor 120, which may include a CPU 122, a GPU 123, and/or an NPU 124. The host 110 may further include a memory controller 130 having a controller memory PHY module 134. The memory controller 130 may couple to the at least one processor 120 via a bus system 115 in performing the various computing functions. The term “bus system” may provide that elements coupled to the “bus system” may exchange information therebetween, directly or indirectly. In different embodiments, the “bus system” may encompass multiple physical connections as well as intervening stages such as buffers, latches, registers, etc. A module may be implemented in hardware, software, or a combination of hardware and software.

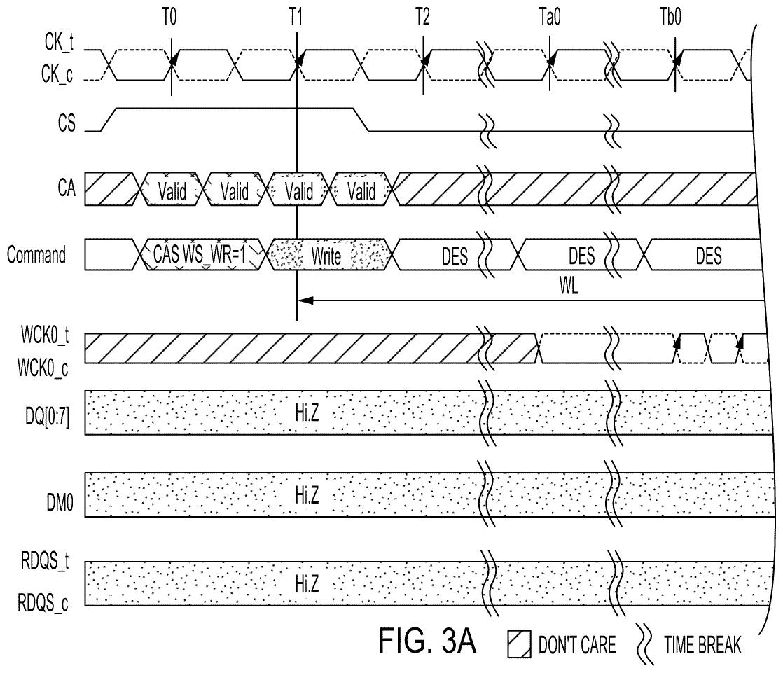

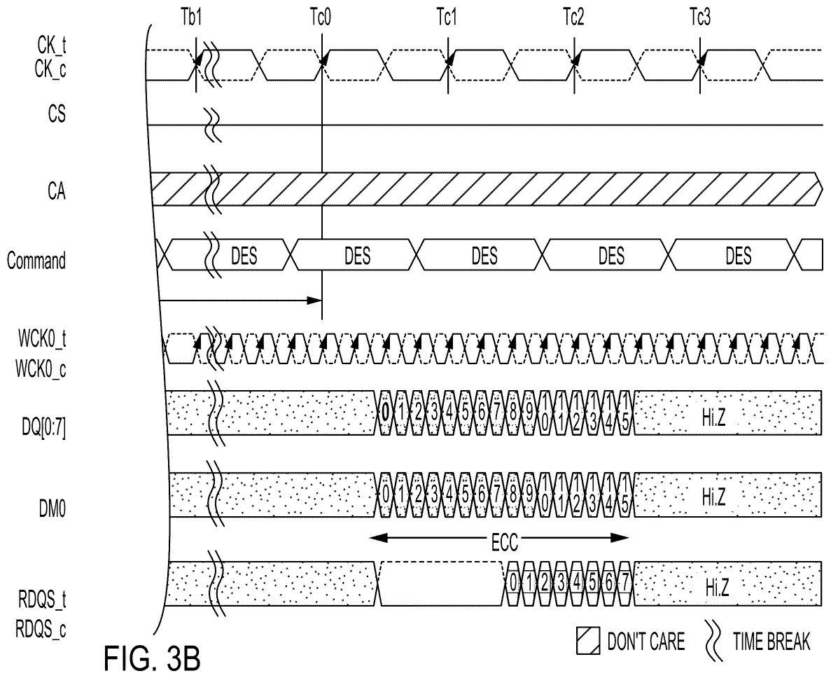

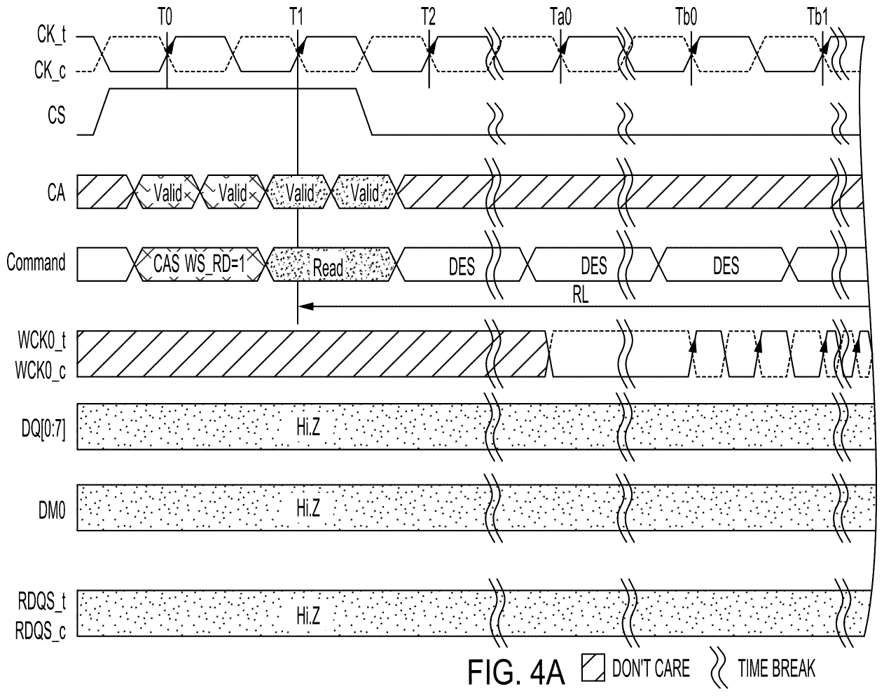

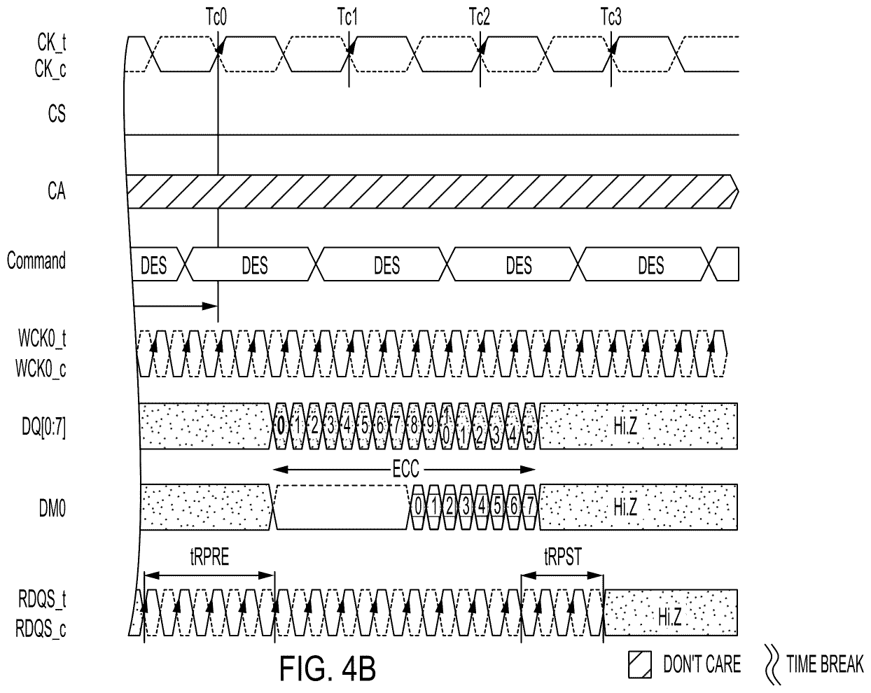

The memory controller 130 may send and/or receive blocks of data, commands, and addresses to other modules, such as the at least one processor 120 and/or the memory system 250. The memory system 250 may include a memory controller 180 with a memory PHY 160 (e.g., memory I/O module or PHY layer) configured to control electrical characteristics (e.g., voltage levels, phase, delays, frequencies, etc.) to provide or to receive signals on connections of the channel 190. For example, memory PHY 160 may be configured to capture (e.g., to sample) data, commands, and addresses from the host 110 via the channel 190 and to output data to the host 110 via the channel 190. Example techniques for communicating on the channel 190 between the memory PHY 160 and the memory controller 130 are shown in the examples of FIG. 3A, FIG. 3B, FIG. 4A, and FIG. 4B. The memory controller 180 may also include data registers 182A-K configured to store data in transit between the host 110 and the memory array 175 and/or to store configuration settings or other data.

The memory system 250 may further include a memory array 175, which may include multiple memory cells (e.g., DRAM memory cells, MRAM memory cells, SRAM memory cells, Flash memory cells) that store values. The host 110 may read data stored in the memory array 175 and write data into the memory array 175, via the channel 190 and the memory PHY 160. The memory array 175 may be divided into a plurality of banks with each bank organized as a plurality of pages.

Application or user data may be processed by the processor 120 and the memory controller 130 in response to instructions/commands to store and/or retrieve such data from the memory system 250. For example, data may be generated during the execution of an application, such as a spreadsheet program that computes values based on other data. As another example, data may be generated during the execution of an application by receiving user input to, for example, a spreadsheet program. As a further example, data may be generated during the execution of a gaming application, which generates information regarding a representation of a scene rendered by a three-dimensional (3-D) application.

The host 110 is coupled to the memory system 250 via the channel 190, which is illustrated for a byte of data, DQ[0:7]. The channel 190 and signaling between the host 110 and the memory system 250 may be implemented in accordance with the JEDEC DRAM specification (e.g., LPDDR5, LPDDR6). As illustrated, the channel 190 includes signal connections of the DQs, a read data strobe (RDQS), a data mask (DM), a data clock (WCK), command and address (CA[0:n]), and command and address clock (CK). The host 110 may use the read data strobe RDQS to strobe (e.g., to clock) data in a read operation to receive the data on the DQs. The memory system 250 may use the data mask DM to mask certain parts of the data from being written in a write operation. The memory system 250 may use the data clock WCK to sample data on the DQs for a write operation. The memory system 250 may use the command and address clock CK to clock (e.g., to receive) the CAs. A signal connection for each of the signaling may include a pin at the host 110, a pin at the memory system 250, and a conductive trace or traces electrically connecting the pins. The conductive trace or traces may be part of a single integrated circuit (IC) on a silicon chip containing the processor 120 and the memory system 250, may be part of a package on package (POP) containing the processor 120 and the memory system 250, or may be part of a printed circuit board (PCB) coupled to both the processor 120 and the memory system 250.

The memory system 250 may include a memory PHY 160 (e.g., a memory I/O module or PHY layer) configured to control electrical characteristics (e.g., voltage levels, phase, delays, frequencies, etc.) to provide or to receive signals on the channel 190. For example, memory PHY 160 may be configured to capture (e.g., to sample) data, commands, and addresses from the host 110 via the channel 190 and to output data to the host 110 via the channel 190. Information transmitted across the channel 190 may be stored in registers in the memory PHY 160 of the memory system 250 as a temporary or short-term storage location prior to longer-term storage in the memory array 175.

The memory system 250 may further include a memory array 175, which may include multiple memory cells (e.g., DRAM memory cells) that store information. The host 110 may read data stored in the memory array 175 and write data into the memory array 175 via the channel 190. Moreover, the memory array 175 may be configured to store metadata such as ECCs (e.g., system or array ECCs) associated with the stored data.

Operations according to some embodiments of this disclosure for storing and retrieving information from memory array 175 may be performed by controlling signals on individual lines of the channel 190. Example embodiments of signaling for a write operation are shown and described with reference to FIG. 3A and FIG. 3B. Example embodiments of signaling for a read operation are shown and described with reference to FIG. 4A and FIG. 4B.

FIG. 3A and FIG. 3B illustrate waveforms of transfer of data through an example channel in a write operation in accordance with certain aspects of the present disclosure. The command and address clock, CK, may be a differential signal having CK_t and CK_c signal connections. The data clock WCK may be a differential signal having WCK0_t and WCK0_c signal connections. The read data strobe RDQS may be a differential signal having RDQS_t and RDQS_c signal connections. The data mask is labeled DM0 to indicate that DM0 corresponds to a lower byte of DQs (DQ[0:7]). At TO (rising edge of CK_t and falling edge of CK_c), a CAS command may be provided by the host 110 for a write operation to the memory system 250. At TI, a write command may be provided by the host 110 to the memory system 250.

After a time period write latency (WL), the host 110 may toggle the data clock WCK0_t and WCK0_c to provide the memory system 250 with clocking for receiving data for write, on the DQ signal connections. At Tc0-Tc2, the memory system 250 may receive 16 bytes of data serially, on each of the DQ[0:7] signal connections and clocked by the data clock WCK0_t and WCK0_c. The memory system 250 may receive 16 bits of the data mask DM0 serially (e.g., based on the data clock WCK0_t and WCK0_c) to mask certain portions of the received data from the write operation. In some examples, the 16 bytes of data and 16 bits of the data mask DM0 may be received by the memory system 250, with each bit of the data mask DM0 masking a corresponding byte of the received data. At Tc0-Tc2, the RDQS_t signal connection may be a Hi-Z condition. In a read operation, the RDQS_t signal connection may be configured to provide a read data strobe (RDQS) from the memory system 250 to the host 110

FIG. 4A and FIG. 4B illustrate waveforms for transfer of data through an example channel in a read operation in accordance with certain aspects of the present disclosure. The command and address clock, CK, may be a differential signal having CK_t and CK_c signal connections. The data clock WCK may be a differential signal having WCK0_t and WCK0_c signal connections. The read data strobe RDQS may be a differential signal having RDQS_t and RDQS_c signal connections. The data mask is labeled DM0 to indicate that DM0 corresponds to a lower byte of DQs (DQ[0:7]). At TO (rising edge of CK_t and falling edge of CK_c), a CAS command may be provided by the host 110 for a read operation to the memory system 250. At TI, a read command may be provided by the host 110 to the memory system 250.

After a time period read latency (RL), the memory system 250 may toggle the read data strobe RDQS to provide the host 110 with clocking to receive data for the read operation on the DQ signal connections. At Tc0-Tc2, the host 110 may receive 16 bytes of data serially, on each of the DQ[0:7] signal connections and clocked by the read data strobe RDQS_t and RDQS_c. Thus, in the example, 16 bytes of data are received by the host 110.

At Tc0-Tc2, the data mask DM0 signal connection may be in a Hi-Z condition. In a write operation, the DM signal connection may be configured to provide a data mask from the host 110 to the memory system 250, which is clocked by WCK0_t and WCK0_c.

Various operations may be performed on rows of a memory bank of a memory system. Commands for performing such operations may, for example, be transmitted by a host device, such as a memory controller of a host device, to a memory system, such as a memory controller of a memory system. Such commands may include commands to read from and/or write to one or more rows of one or more banks of the memory system. Another example command may be an activate command which may activate one or more rows of one or more memory banks for reading and/or writing of data. As another example, a precharge command may deactivate a currently activated row. A refresh command may, as described, refresh a charge on a row of a memory module to prevent data loss.

Commands, such as read, write, precharge, refresh, and activate commands may be transmitted from a host device to a memory system via a command bus, such as a CA[0:n] or other command bus. A bandwidth of the command bus may be limited. For example, with increasing numbers of banks in memory systems, such as DRAM, a command bus between a host device and the memory system may become increasingly congested. Reductions in congestion may lead to performance improvement and a reduction in power consumption in memory systems. For example, congestion of a command bus may lead to more frequent toggling of a CK clock, which may increase power consumption and reduce a number of column command slots, thereby reducing performance.

Merged precharge, refresh, and activate commands, as discussed herein, may reduce bus congestion through combination of precharge, refresh, activate, read, and/or write commands into a single command transmitted via the command bus. As one example, such merging may be particularly useful in DRAM where bank hashing algorithms may be used to improve a bank spread. In some cases, a number of banks may exceed twelve. Bank hashing may increase a number of active banks, and a greater number of active banks may require transmission of a greater number of precharge commands before scheduling of a refresh command. If a same row is to be activated following a refresh operation, a separate, additional, activate command for the row may be sent as well. Furthermore, precharge, refresh, and activate operations may require a higher portion of command bus bandwidth as a refresh rate increases. As one particular example, a refresh in automotive DRAM systems may be 4×, 8×, or higher. As one example, in LPDDR5 bank group (BG), a single refresh interval (tREFI) for DRAM, may include sixteen scheduled refreshes, requiring a precharge operation, a refresh operation, and, in some cases, an activate operation at every interval. In some cases, a 1% or greater performance overhead may result from transmission of separate precharge, refresh, and activate commands. Combination of such commands into merged commands may reduce or eliminate the performance overhead. Furthermore, smart scheduling may be implemented by a memory controller allowing for flexible scheduling based on bank usage, and a number of wasted activate operations may be reduced by allowing an activate that has opened a row to finish before a row is changed, such as when a refresh operation occurs. Thus, separate precharge, refresh, and activate commands transmitted via a command bus may require a high amount of available command bus bandwidth, reducing an amount of command bus bandwidth available for other commands, reducing a utilization of the memory system, and/or increasing power consumption of the memory system and/or host device. Such effects may increase in severity as a refresh rate of a memory system and/or a number of banks of a memory system increases. Reductions in command bus congestion achieved through use of merged precharge, refresh, and activate commands may result in enhanced efficiency in handling per bank refreshes, a reduced number of all bank refreshes through increased availability of command bus slots for command transmission, improvements in efficiency and latency through a reduced number of overhead cycles, and enhanced availability of command slots of a command bus for transmission of other commands. Such improvements may enhance memory system utilization and reduce power consumption through a reduction in a total number of command bus cycles. As one particular example, a number of cycles may be reduced by up to and in excess of 2%.

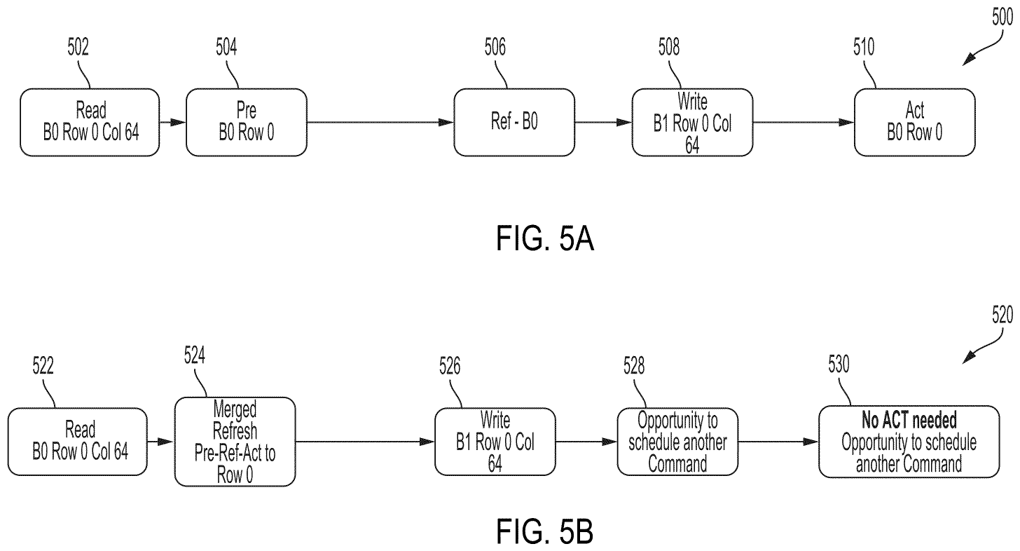

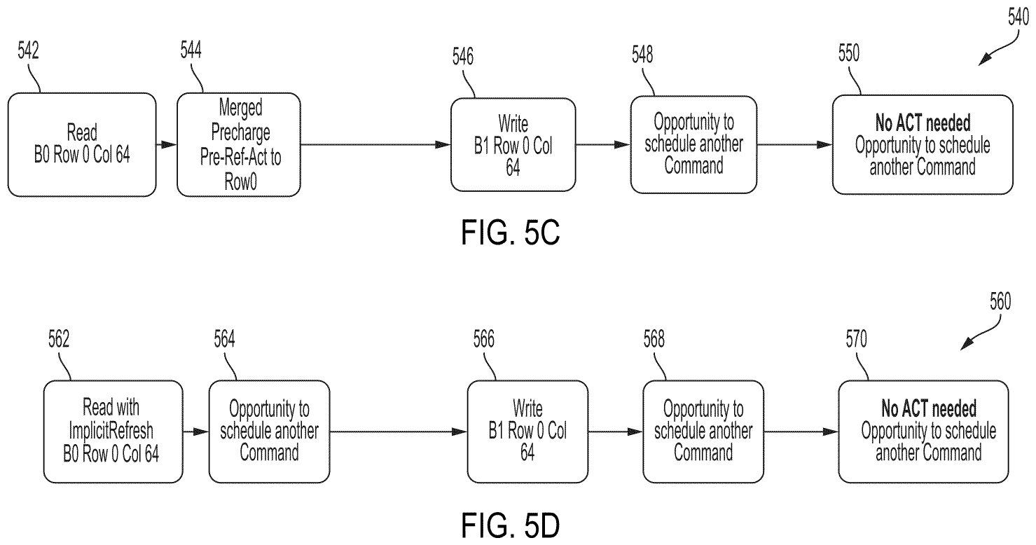

An example flow diagram 500 of a sequence of non-merged commands for one or more rows of one or more banks of a memory module is shown in FIG. 5A. For example, at block 502, a read command for bank 0, row 0, column 64 may transmitted from a host device to a memory system, such as to a memory controller of a memory system, via a bus, such as a command bus. The memory system may then execute the read command. At block 504, a precharge command for bank 0, row 0, which may be an open row of bank 0, may be transmitted from the host to the memory system, such as to the memory controller of the memory system, via a bus, such as via a command bus. The memory system may then execute the precharge command. At block 506, a refresh command for bank 0 may be transmitted from the host to the memory system, such as to the memory controller of the memory system, via a bus, such as via a command bus. The memory system may then execute the refresh command. At block 508, a write command for bank 1, row 0, column 64 may be transmitted from the host device to the memory system, such as to the memory controller of the memory system, via a bus, such as the command bus. The memory system may then execute the write command. At block 510, an activate command for bank 0, row 0, which may be an open row of bank 0, may be transmitted from the host device to the memory system, such as to the memory controller of the memory system, via a bus, such as the command bus. The memory system may then execute the activate command. Thus, the sequence of commands of diagram 500 may require transmission of five commands via a command bus to perform the read, precharge, refresh, write, and activate operations described.

An example flow diagram 520 of a sequence of commands including a merged refresh command is shown in FIG. 5B. For example, at block 522, a read command for bank 0, row 0, column 64 may be transmitted from a host device to a memory system, such as to a memory controller of a memory system, via a bus, such as a command bus. Row 0 may be an open row of bank 0. The memory system may then execute the read command. At block 524, a merged command, such as a command to perform a refresh operation on one or more banks and a precharge operation and an activate operation on one or more rows, such as row 0, which may be an open row of bank 0, and/or another row, of one or more banks, such as bank 0 and/or another bank, may be transmitted from a host device to a memory system, such as to a memory controller of a memory system, via a bus, such as a command bus. The memory system may then execute the precharge operation, the refresh operation, and the activate operation. For example, the memory system may execute the precharge operation and the refresh operation before a write operation described with respect to block 526 and may perform an activate operation after the write operation based on the single command described with respect to block 524. The command of block 524 may, for example, have a refresh command format and may include an indication to perform a refresh operation and an activate operation in addition to the refresh operation. At block 526, a write command for bank 1, row 0, column 64 may be transmitted from the host device to the memory system, such as to the memory controller of the memory system, via a bus, such as the command bus. The memory system may then execute the write command. Thus, the write command of block 526 may be moved forward compared to the write command of block 508 of FIG. 5A, as the host device may not need to generate and transmit a separate refresh command. As a result of the transmission of the merged command at block 524, additional opportunities at blocks 528 and 530 may be available for transmission of other commands from the host device to the memory system via the bus. For example, the write command transmitted at block 508 of FIG. 5A may be moved to forward to block 526 of FIG. 5B, and the activate command transmitted at block 510 of FIG. 5A may not be required. Thus, up to three clock cycles of the command bus may be saved through use of the merged refresh command, one clock cycle corresponding to a precharge command, and two clock cycles corresponding to an activate command. As another example, a merged refresh command may include a command to perform a refresh operation on a first, current, bank and a second bank and a precharge operation on a first, current, row of the first bank and a second, corresponding, row, of the second bank, without including a command to perform an activate operation.

An example flow diagram 540 of a sequence of commands including a merged precharge command is shown in FIG. 5C. For example, at block 542, a read command for bank 0, row 0, column 64 may be transmitted from a host device to a memory system, such as to a memory controller of a memory system, via a bus, such as a command bus. Row 0 may, for example, be an open row of bank 0. The memory system may then execute the read command. At block 544, a merged command, such as a command to perform a precharge operation, a refresh operation, and an activate operation on one or more rows, such as row 0, which may be an open row, and/or another row, of one or more banks, such as bank 0 and/or another bank, may be transmitted from a host device to a memory system, such as to a memory controller of a memory system, via a bus, such as a command bus. The memory system may then execute the precharge operation, the refresh operation, and the activate operation. For example, the memory system may execute the precharge operation and the refresh operation before a write operation described with respect to block 546 and may perform an activate operation after the write operation based on the single command described with respect to block 544. The command of block 544 may, for example, have a precharge command format and may include an indication to perform a refresh operation and an activate operation in addition to the precharge operation. At block 546, a write command for bank 1, row 0, column 64 may be transmitted from the host device to the memory system, such as to the memory controller of the memory system, via a bus, such as the command bus. The memory system may then execute the write command. Thus, the write command of block 546 may be moved forward compared to the write command of block 508 of FIG. 5A, as the host device may not need to generate and transmit a separate refresh command. As a result of the transmission of the merged command at block 544, additional opportunities at blocks 548 and 550 may be available for transmission of other commands from the host device to the memory system via the bus. For example, the write command transmitted at block 508 of FIG. 5A may be moved to forward to block 546 of FIG. 5C, and the activate command transmitted at block 510 of FIG. 5A may not be required. Thus, up to three clock cycles of the command bus may be saved through use of the merged precharge command, one clock cycle corresponding to a refresh command, and two clock cycles corresponding to an activate command. As another example, a merged precharge command may include a command to perform a refresh operation on a first, current, bank and a second bank and a precharge operation on a first, current, row of the first bank and a second, corresponding, row, of the second bank, without including a command to perform an activate operation.

An example flow diagram 560 of a sequence of commands including a merged read or write command is shown in FIG. 5D. The following example is based on a merged read command, although a similar sequence of commands could be realized with a merged write command. For example, at block 562, a merged read command, such as a command to perform a read operation, a precharge operation, a refresh operation, and an activate operation on one or more rows of one or more banks of the memory system may be transmitted from a host device to a memory system, such as to a memory controller of a memory system, via a bus, such as a command bus. For example, the read operation may be a read operation for bank 0, row 0, column 64, the precharge operation may be for bank 0, row 0, the refresh operation may be for bank 0, and the activate operation may be for bank 0, row 0. Row 0 may, for example, be an open row of bank 0. The merged read command may have a read command format and may include an indication to perform a read operation, a precharge operation, a refresh operation, and an activate operation on one or more rows, such as row 0, which may be an open row, and/or another row, of one or more banks, such as bank 0 and/or another bank. The memory system may then execute the read operation, the precharge operation, the refresh operation, and the activate operation. For example, the memory system may execute the read operation, the precharge operation, and the refresh operation before a write operation described with respect to block 566 and may perform an activate operation after the write operation based on the single command described with respect to block 562. Thus, the bus may be available for transmission of another command at block 564, as a separate precharge command need not be transmitted at block 564. At block 566, a write command for bank 1, row 0, column 64 may be transmitted from the host device to the memory system, such as to the memory controller of the memory system, via a bus, such as the command bus. The memory system may then execute the write command. Thus, the write command of block 566 may be moved forward compared to the write command of block 508 of FIG. 5A, as the host device may not need to generate and transmit a separate refresh command. As a result of the transmission of the merged command at block 562, additional opportunities at blocks 564, 568, and 570 may be available for transmission of other commands from the host device to the memory system via the bus. For example, the write command transmitted at block 508 of FIG. 5A may be moved to forward to block 566 of FIG. 5D, the activate command transmitted at block 510 of FIG. 5A may not be required, and the precharge command of block 504 may not be required. Thus, up to four clock cycles of the command bus may be saved through use of the merged read or write commands, one clock cycle corresponding to a precharge command, one clock cycle corresponding to a refresh command, and two clock cycles corresponding to an activate command. As another example, a merged read or write command may include a command to perform a refresh operation on a first, current, bank and a second bank, a precharge operation on a first, current, row of the first bank and a second, corresponding, row, of the second bank, and a write operation on the first, current, row of the first bank, without including a command to perform an activate operation. First row, first bank, second row, and second bank, as used herein, may refer to any particular row or bank of a memory module and need not refer to a first row or a first bank and/or a second row and a second bank in a particular order of rows in the memory module. Thus, while the first row may be distinct from the second row, the first row and second row need not be a first and second row in order of rows of a memory module. Furthermore, the first row and the second row need not be adjacent rows of a memory module. Likewise, while the first bank may be distinct from the second bank, the first bank need not be a first and second bank in order of banks of a memory module. Furthermore, the first bank and the second bank need not be adjacent banks of a memory module.

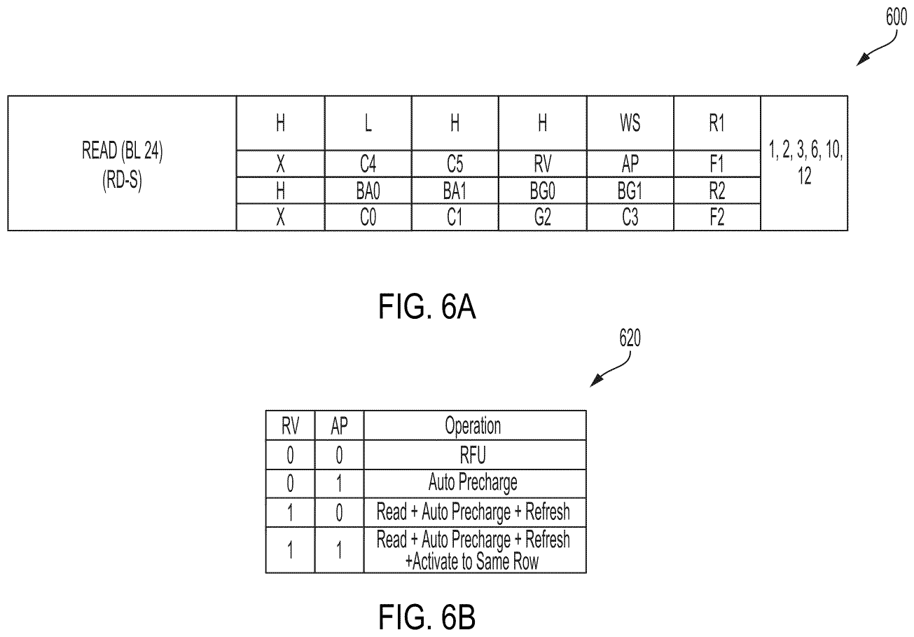

In generating, transmitting, and receiving commands for performing precharge, refresh, and activate operations on one or more rows of a memory bank, various command formats may be used. As one particular example, command message formats for transmission of commands using a command bus according to JEDEC double data rate (DDR) standards, such as LPDDR5, LPDDR6, and/or other JEDEC DDR standards may be used. For example, particular bits of commands, such as read commands, write commands, precharge commands, or refresh commands, may be repurposed for indicating that a read command, write command, precharge command, and/or refresh command includes a command to perform one or more additional operations. FIG. 6A is a chart 600 of bits of an example read command in accordance with certain aspects of the present disclosure. Bits 4 and 5 of the second row of the chart 600, marked RV and AP, which may correspond to command bus bits, may be used to indicate what operations are to be performed based on the read command of chart 600. The bit marked RV may be configured as a reserved bit, and the bit marked AP may be configured an auto-precharge bit when a system is not configured to support merged precharge, refresh, and activate commands. For example, the bits marked RV and AP of the second row of the chart 600 may be repurposed to indicate operations, such as precharge, refresh, and activate operations, that are to be performed in addition to the read operation in systems that support merged precharge, refresh, and activate commands. In some aspects, the read command of chart 600 may be a read command formatted according to the a JEDEC LPDDR standard. In some aspects, the command of chart 600 may be a Read Block (BL) 24 command, although similar modifications may be made to a Write Block 24 command, a Read Block 48 command, or a Write Block 48 command. For example, a write command may be modified similarly to the read operation of chart 600, such as through modification of the same bits, to indicate additional operations that are to be performed. FIG. 6B is a chart 620 of bit values of a read command, such as the read command of chart 600 of FIG. 6A, and corresponding operations to be performed in response to the read command in accordance with certain aspects of the present disclosure. For example, if the bit marked RV is set to zero and the bit marked AP is set to zero, a legacy read command may be performed, such as a backwards compatible read command. If the bit marked RV is set to zero and the bit marked AP is set to one, a read command and an auto precharge operation may be performed on one or more rows of a bank, such as an open row of a bank, indicated by the BA0, BA1, BG0, and BG1 bits. If the bit marked RV is set to one and the bit marked AP is set to zero, a read operation and an auto precharge operation may be performed on one or more rows of the bank, such as an open row of the bank, indicated by the BA0, BA1, BG0, and BG1 bits, and a refresh operation may be performed on the bank. If the bit marked RV is set to one and the bit marked AP is set to one, a read operation and an auto precharge operation may be performed on one or more rows of the bank, such as an open row of the bank, indicated by the BA0, BA1, BG0, and BG1 bits, a refresh operation may be performed on the bank, and an activate operation may be performed on the same one or more rows, such as the open row of the bank. Such a merged read, precharge, refresh, and/or activate command may be transmitted via the command bus, for example, to schedule additional page hits following a refresh operation on a same row, to indicate to the memory system to re-open a same row following a refresh operation by performing the activate operation on the same row. In some aspects, the precharge and the activate operation may be performed on corresponding rows of two banks of a bank pair. Likewise, in some aspects the refresh operation may be performed on two banks of a bank pair. In some aspects, the bank pair may be fixed, while in other aspects the bank pair may be configurable. The read command described with reference to FIGS. 6A-B may be particularly useful in an eight bank mode where only a single bank is refreshed at a time.

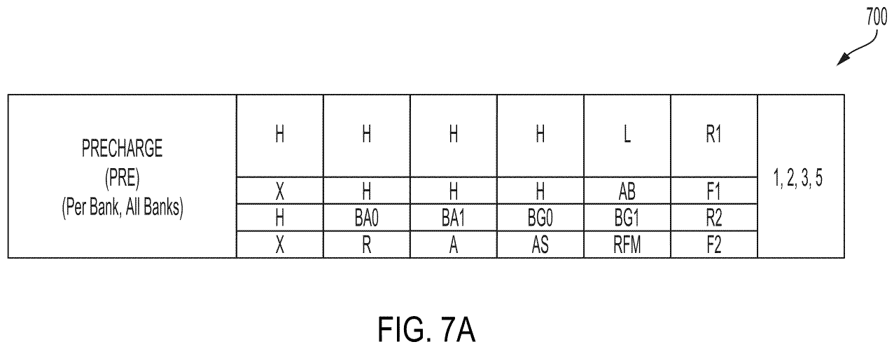

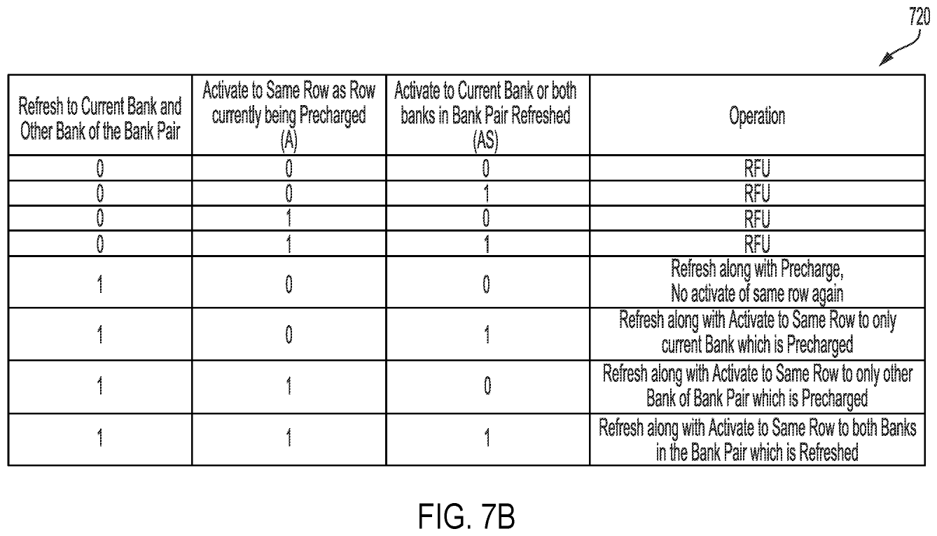

FIG. 7A is a chart 700 of bits of an example precharge command in accordance with certain aspects of the present disclosure. Bits 2, 3, and 4 of the fourth row of the chart, marked R, A, and AS, which may correspond to command bus bits, or other bits, may be used to indicate what operations are to be performed based on the precharge command of chart 700. The bits marked R, A, and AS may be configured as voltage (V) bits when a system is not configured to support merged precharge, refresh, and activate commands. For example, the bits marked R, A, and AS may be repurposed to indicate operations, such as refresh and activate operations, that are to be performed in addition to the precharge operation. In some aspects, the precharge command of chart 700 may be a precharge command formatted according to a DDR JEDEC standard, with one or more bits repurposed. FIG. 7B is a chart 720 of bit values of a precharge command, such as the precharge command of chart 700 of FIG. 7A, and corresponding operations to be performed in response to the precharge command in accordance with certain aspects of the present disclosure. For example, the bit marked R may be used to indicate a refresh operation, the bit marked A may be used to indicate an activate applied to a row to which the precharge operation is applied, such as an open row, and the bit marked AS may be used to indicate an activate to the same memory bank to which the precharge operation is applied or to both the same memory bank and another memory bank of a bank pair including the memory bank to which the precharge operation is applied. For example, values, corresponding to the R bit, the A bit, and the AS bit, of 000, 001, 010, and 100 may be reserved for legacy operations, such as operations associated with a precharge command when the command is not a merged precharge command. A bank to which the merged precharge command is to be applied may be indicated by the BA0, BA1, BG0, and BG1 bits of the chart 700. Such a bank indication may indicate a bank pair, such as by indicating a first bank that is a member of a bank pair with a second bank. Values, corresponding to the R bit, the A bit, and the AS bit, of 100 may indicate that a precharge operation is to be performed on a row of a bank, such as an open row, and/or a corresponding row of another bank that is a member of a bank pair with the bank and a refresh operation is to be performed on the bank, and, in some cases, another bank in a bank pair with the bank. Values, corresponding to the R bit, the A bit, and the AS bit, of 101 may indicate that a precharge operation is to be performed on a row of a current bank of a bank pair, such as an open row, and a corresponding row of another bank of the bank pair, that a refresh operation is to be performed on the current bank the other bank of the bank pair, and an activate operation is to be performed on the row of the current bank, such as the open row. Values, corresponding to the R bit, the A bit, and the AS bit, of 110 may indicate that a precharge operation is to be performed on a row of a current bank of a bank pair, such as an open row, that a refresh operation is to be performed on the current bank and another bank of the bank pair, and an activate operation is to be applied to a row of the other bank of the bank pair corresponding to the row of the current bank of the bank pair. Values, corresponding to the R bit, the A bit, and the AS bit, of 111 may indicate that a precharge operation is to be performed on a row of a current bank of a bank pair, such as an open row, that a refresh operation is to be performed on the current bank of the bank pair and another bank of the bank pair, and an activate operation is to be applied to a the row of the current bank of the bank pair, such as the open row, and a corresponding row of the other bank of the bank pair. In some aspects, the bank pair may be fixed, while in other aspects a bank pair may be configurable in the merged precharge command, such as through use of one or more spare bits.

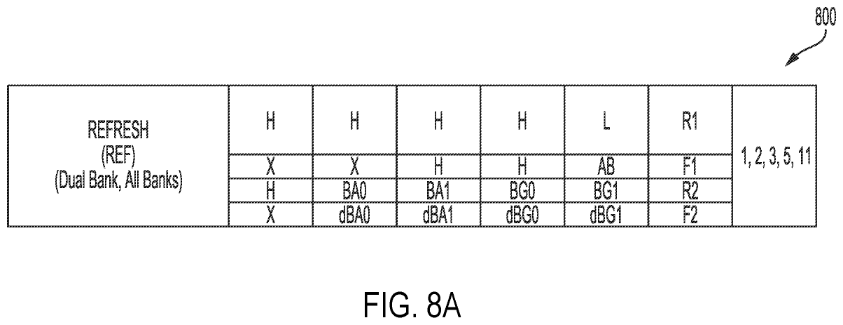

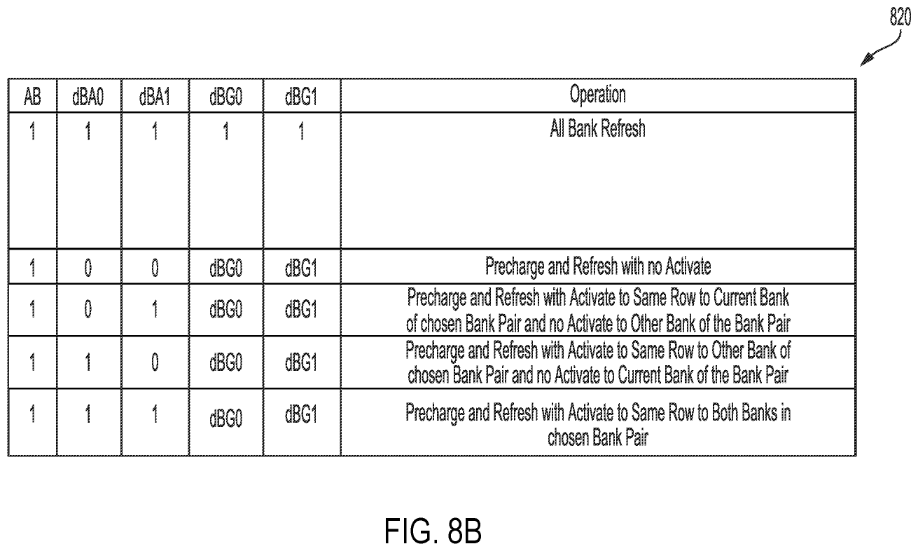

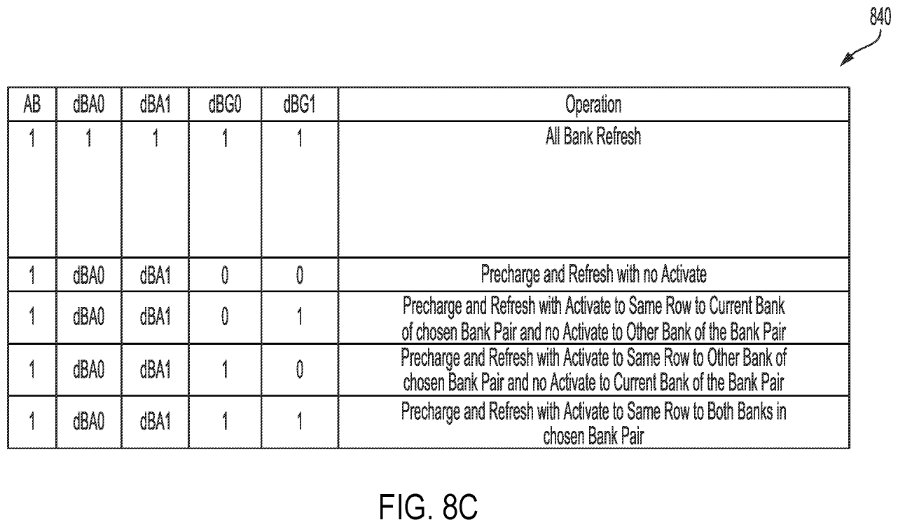

FIG. 8A is a chart 800 of bits of an example refresh command in accordance with certain aspects of the present disclosure. A refresh command may be configured to include instructions to perform a precharge, refresh, and activate operation on one or more rows of a particular bank of a flexible bank group or to a flexible bank of a particular bank group. Bit 5 of the second row of the chart 800, when set to 1, may indicate that all banks are to be refreshed. A bank to be precharged and refreshed may be indicated by bits BA0, BA1, BG0, and BG1 of the third row of the chart 800. Bits dBA0, dBA1, dBG0, and dBG1 may indicate whether a refresh operation, a precharge and refresh operation, or a precharge, refresh, and activate operation are to be performed, and which rows and/or banks to which the operations are to be applied. For example, the bits marked dBA0, dBA1, dBG0, and dBG1 may be repurposed to indicate operations, such as refresh, precharge, and activate operations, that are to be performed. In some aspects, the refresh command of chart 800 may be a refresh command formatted according to a DDR JEDEC standard, with one or more bits repurposed.

FIG. 8B is a chart 820 of bit values of a refresh command, such as the refresh command of chart 800 of FIG. 8A, and corresponding operations to be performed in response to the refresh command in accordance with certain aspects of the present disclosure. For example, the bit values and corresponding operations of FIG. 8B may correspond to a configuration of a memory device and/or host to support a fixed bank for the operations but allow for selection of banks having a same bank number from different bank groups. For example, a current bank of a bank pair to which a precharge and/or refresh operation is to be applied may be indicated by bits BA0, BA1, BG0 and BG1, while another bank in the bank pair may be indicated by BA0, BA1, dBG0 and dBG1, allowing for flexible selection of bank groups for the bank pair using dBG0 and dBG1 with a particular bank fixed by the values of BA0 and BA1. For example, when values of the bits marked AB, dBA0, dBA1, dBG0, and dBG1 are all 1, the command may indicate that an all bank refresh operation is to be performed. In some aspects, the memory system may enable or disable an all bank refresh using a particular bit status, such as a particular mode register write (MRW) bit for backward compatibility. For example, an MRW bit may be written with a value of disable at runtime, or boot up software may write an MRW bit with a value of disable. If AB, dBA0, and dBA1 are set to 100, the command may indicate that a precharge operation is to be performed on a row, such as an open row, of a current bank indicated by the BA0, BA1, BG0, and BG1 bits and a corresponding row of the other bank of the bank pair and that a refresh operation is to be performed on both banks of the bank pair. If AB, dBA0, and dBA1 are set to 101, the command may indicate that a precharge operation is to be performed on a row, such as an open row, of a current bank of the bank pair and a corresponding row of another bank of the bank pair, that a refresh operation is to be performed on both banks of the bank pair, and an activate operation is to be applied to the row, such as the open row, of the current bank indicated by the BA0, BA1, BG0, and BG1 bits. If AB, dBA0, and dBA1 are set to 110, the command may indicate that a precharge operation is to be performed on a row, such as an open row, of a current bank of the bank pair and a corresponding row of another bank of the bank pair, that a refresh operation is to be applied to both the current bank, indicated by the BA0, BA1, BG0, and BG1 bits, and the other bank of the bank pair, indicated by the BA0, BA1, dBG0, and dBG1 bits, and that an activate operation is to be applied to the corresponding row of the other bank of the bank pair. The other bank of the bank pair may, for example, be a corresponding bank of a different bank group, such as a bank having a same bank number as the current bank. If AB, dBA0, and dBA1 are set to 111, the command may indicate that a precharge operation is to be performed on a row of a current bank of the bank pair and a corresponding row of another bank of the bank pair, that a refresh operation is to be performed on both banks of the bank pair, and an activate operation is to be applied to both the row of the current bank indicated by the BA0, BA1, BG0, and BG1 bits and the corresponding row of the other bank indicated by the BA0, BA1, dBG0, and dBG1 bits. Thus, if a row of current bank 1 of bank group BG0 is precharged and activated, the corresponding row of corresponding bank 1 of BG1 may be precharged and activated as well.

FIG. 8C is a chart 840 of bit values of a refresh command, such as the refresh command of chart 800 of FIG. 8A, and corresponding operations to be performed in response to the refresh command in accordance with certain aspects of the present disclosure. For example, the bit values and corresponding operations of FIG. 8C may correspond to a configuration of a memory device and/or host to support a fixed bank group but allow for selection of different banks within the fixed bank group to form the bank pair. For example, a current bank of a bank pair to which a precharge and/or refresh operation is to be applied may be indicated by bits BA0, BA1, BG0 and BG1, while another bank in the refresh pair may be indicated by dBA0, dBA1, BG0 and BG1, allowing for flexible selection of banks within a fixed bank group. Similar to the description with respect to FIG. 8B, when values of the bits marked AB, dBA0, dBA1, dBG0, and dBG1 are all 1, the command may indicate that an all bank refresh operation is to be performed. If AB, dBG0, and dBG1 are set to 100, the command may indicate that a precharge command is to be applied to a row, such as an open row, of a current bank of a bank pair and a corresponding row of another bank of the bank pair and that a refresh operation is to be performed the current bank and the other bank of the bank pair. If AB, dBG0, and dBG1 are set to 101, the command may indicate that a precharge operation is to be performed on a row, such as an open row, of a current bank of a bank pair and a corresponding row of another bank of the bank pair, that a refresh operation is to be performed on the current bank and the other bank of the bank pair, and that an activate operation is to be applied to the row, such as the open row, of the current bank indicated by the BA0, BA1, BG0, and BG1 bits. If AB, dBG0, and dBG1 are set to 110, the command may indicate that a precharge operation is to be performed on a row, such as an open row, of a current bank of a bank pair and a corresponding row of another bank of the bank pair, that a refresh operation is to be applied to the current bank, indicated by the BA0, BA1, BG0, and BG1 bits, and the other bank of the bank pair, indicated by the dBA0, dBA1, BG0, and BG1 bits, and that an activate operation is to be applied to the corresponding row of the other bank of the bank pair. The other bank of the bank pair may, for example, be a different bank of the fixed bank pair indicated by dBA0 and dBA1. If AB, dBA0, and dBA1 are set to 111, the command may indicate that a precharge operation is to be applied to a row, such as an open row, of a current bank of the bank pair and a corresponding row of a second bank of the bank pair, a refresh operation is to be performed on both the current bank of the bank pair and the other bank of the bank pair, and an activate operation is to be applied to the row, such as the open row of the current bank of the bank pair indicated by the BA0, BA1, BG0, and BG1 bits and the corresponding row of the other bank of the bank pair indicated by the dBA0, dBA1, BG0, and BG1 bits. Thus, if a row, such as an open row, of a current bank of a bank group is precharged and activated, the corresponding row of a different bank of the bank group may be precharged and activated as well.

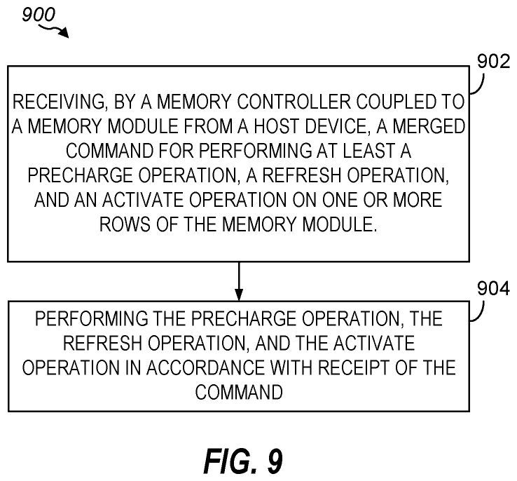

Operations for supporting merged memory commands according to aspects of the disclosure are described with respect to FIG. 9. A merged memory command issued by the host to the memory device of method 900 causes the memory system 250 to perform operations, beginning at block 902, with receiving, by a memory controller coupled to a memory module from a host device, a merged command for performing at least a precharge operation, a refresh operation, and an activate operation on one or more rows of the memory module. The command may, for example, be a merged memory command to instruct a memory system to perform multiple operations, such as a precharge operation, a refresh operation, and an activate operation, in a single command. In some aspects, a merged command may include only (1) a command for performing a precharge and a refresh operation, (2) a precharge, a refresh, and a write operation, or (3) a precharge, a refresh, and a read operation with no activate operation. In some aspects, the command may be a command having a write command format, a read command format, a precharge command format, or a refresh command format. For example, the command may be a read or write command including an indication to perform a precharge operation, a refresh operation, and an activate operation, in addition to a read operation or write operation indicated by the read or write command. As another example, the command may be a precharge command including an indication to perform a refresh operation and an activate operation, in addition to a precharge operation indicated by the precharge command. As another example, the command may be a refresh command including an indication to perform a precharge operation and an activate operation, in addition to a refresh operation indicated by the refresh command. In some aspects, one or more bits of a command used to indicate a read operation, a write operation, a precharge operation, or a refresh operation in systems that do not support merged memory commands, as disclosed herein, may be repurposed for indicating that additional operations, such as precharge, refresh, and activate operations, are to be performed. The command may be transmitted via a command bus between the host device and the memory controller.

When the format of the command is a read command or a write command, the command may include an indication that the precharge operation and the activate operation are to be performed on a first row of a first bank of the memory module and that the refresh operation is to be performed on the first bank of the memory module. The first row may, for example, be an open row. As another example, when the format of the command is a read command or a write command, the command may further include an indication that the precharge operation and the activate operation is to be performed on a second row of a second bank of the memory module, where the second row corresponds to the first row, such as by having a same row number as the first row, and where the first and second banks are members of a bank pair.

When the format of the command is a precharge command format, the command may include a first indication that the precharge operation is to be performed on a first row of a first bank of the memory module and a second row of a second bank of the memory module, that the refresh operation is to be performed on the first bank and the second bank, and the activate operation is to be performed on the first row of the first bank of the memory module. The first row may, for example, be an open row of the first bank. The first row may, for example, be tracked in memory, such as stored in an indication in the memory module or another memory, as the precharge command may, in some aspects, not include an indication of the first, or open, row. The second row of the second bank may, for example correspond to the first row of the first bank, such as by having a same row number as the first row. The first and second banks may, for example, be first and second banks of a bank pair of the memory module. Alternatively or additionally, the command may include a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module. Alternatively or additionally, the command may include a third indication that the precharge operation is to be performed on the first row of the first bank of the memory module and the second row of the second bank of the memory module, that the refresh operation is to be performed on the first bank and the second bank, and that the activate operation is to be performed on the first row of the first bank of the memory module and the second row of the second bank of the memory module. For example, the first indication may include a first bit pattern of one or more bits of the command, the second indication may include a second bit pattern of one or more bits of the command, and the third indication may include a third bit pattern of one or more bits of the command. In some aspects, the command may include an indication that the precharge, refresh, and activate operations are to be performed only on a single bank and/or row of the single bank. For example, a combined precharge, refresh, and/or activate command may indicate that the precharge, refresh, and/or activate operations are to be performed on a single bank and/or row of the single bank when the memory module is operating in an eight bank mode or an LPDDR4 mode, such as when the memory module is configured in the eight bank mode or is a LPDDR4 memory module configured according to the LPDDR4 specification. As one particular example, the command may comprise an indication that the precharge operation is to be performed on a first row of a first bank of the memory module, that the refresh operation is to be performed on the first bank of the memory module, and that the activate operation is to be performed on the first row of the first bank of the memory module.

When the format of the command is a refresh command format, the command may include a first indication that the precharge operation is to be performed on a first row of a first bank of the memory module and a second row of a second bank of the memory module, that the refresh operation is to be performed on the first bank and the second bank, and that the activate operation is to be performed on the first row of the first bank of the memory module. The first row may, for example, be an open row of the first bank. The first and second banks may, for example, be first and second banks of a bank pair of the memory module. The second row of the second bank of the memory module may, for example, correspond to the first row of the first bank of the memory module, such as by having a same row number as the first row of the first bank of the memory module. Alternatively or additionally, the command may include a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module. Alternatively or additionally, the command may include a third indication that the precharge operation is to be performed on the first row of the first bank and the second row of the second bank, that the refresh operation is to be performed on the first bank and the second bank, and that the activate operation is to be performed on the first row of the first bank and the second row of the second bank. For example, the first indication may include a first bit pattern of one or more bits of the command, the second indication may include a second bit pattern of one or more bits of the command, and the third indication may include a third bit pattern of one or more bits of the command. Thus, an activate operation in accordance with the merged command may be applied only to a row of the current bank of the bank pair, only to a corresponding row of the other bank of the bank pair only to a row, or to both rows of both banks of the bank pair. In some aspects the first bank and the second bank may be banks having a same, fixed, bank number of different bank groups, and in some aspects the first bank and the second bank may be banks of a same, fixed, bank group having different bank numbers. In some aspects, one or more bits of the command may include an indication of a fixed bank number and a variable bank group for the first bank and the second bank or a variable bank number and a fixed bank group for the first bank and the second bank. In some aspects, both a bank number and a bank group of the first bank and the second bank may be variable and may be indicated by one or more bits of the command. In some aspects, a host device and memory module may be configured to support commands including indications of fixed or variable first and second banks in merged memory commands.

At block 904, the memory controller may perform the precharge operation, the refresh operation, and the activate operation in accordance with receipt of the command. For example, based on the command, the memory controller may perform a precharge operation and an activate operation on one or more rows of one or more memory banks and a refresh operation on one or more of the memory banks. Thus, a memory controller may perform multiple operations, such as a precharge operation, a refresh operation, and an activate operation, in response to receipt of a single command for performing the operations.

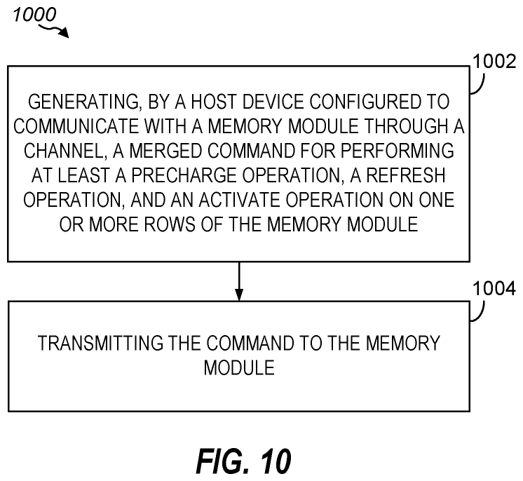

Operations for supporting merged memory commands according to aspects of the disclosure are described in FIG. 10. A merged memory command issued by the host to the memory device of method 1000 causes the memory system 250 to perform operations, beginning at block 1002, with generating, by a host device configured to communicate with a memory module of the memory system through a channel, a merged command for performing at least a precharge operation, a refresh operation, and an activate operation on one or more rows of the memory module. The command may, for example, be a command as described with respect to the method 900 of FIG. 9. The channel may, for example, include a command bus for transmission of commands, such as the merged commands described herein, from the host device to the memory module. Generating the command may include, for example, determining one or more rows of one or more banks of the memory module on which precharge, refresh, and activate operations are to be performed.

At block 1004, the command may be transmitted to the memory module. For example, the command may be transmitted via a command bus of a channel through which the host device is configured to communicate with the memory module of the memory system.

A wireless communications device may include a memory system as illustrated in at least FIG. 1 and FIG. 2 and configured to receive and output data from the memory array and support merged memory commands for improved bus utilization in volatile memory on the memory array. The memory system according to any of the aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, or avionics systems.

In one or more aspects, techniques for memory storage and retrieval may include additional aspects, such as any single aspect or any combination of aspects described below or in connection with one or more other processes or devices described elsewhere herein. In a first aspect, supporting data operations may include an apparatus configured to perform operations comprising receiving, from a host device, a merged command for performing at least a precharge operation, a refresh operation, and an activate operation on one or more rows of the memory module and performing the precharge operation, the refresh operation, and the activate operation in accordance with receipt of the merged command.

Additionally, the apparatus may perform or operate according to one or more aspects as described below. In some implementations, the apparatus includes a wireless device, such as a UE. In some implementations, the apparatus includes a remote server, such as a cloud-based computing solution, which receives image data for processing to determine output image frames. In some implementations, the apparatus may include at least one processor, and a memory coupled to the processor. The processor may be configured to perform operations described herein with respect to the apparatus. In some other implementations, the apparatus may include a non-transitory computer-readable medium having program code recorded thereon and the program code may be executable by a computer for causing the computer to perform operations described herein with reference to the apparatus. In some implementations, the apparatus may include one or more means configured to perform operations described herein. Operations, as described herein, may include receiving commands, transmitting commands, precharge operations, refresh operations, activate operations, and other operations. In some implementations, a method may include one or more operations described herein with reference to the apparatus. In some implementations, the apparatus may include a memory controller coupled to a memory module through a first channel and configured to access data stored in the memory module through the first channel. The memory controller may be configured to perform or operate according to one or more aspects as described herein.

In a second aspect, in combination with the first aspect, the merged command is received by the memory controller from the host device via a command bus.

In a third aspect, in combination with one or more of the first aspect or the second aspect, a format of the merged command is a read command format or a write command format.

In a fourth aspect, in combination with one or more of the first aspect through the third aspect, the merged command comprises an indication that the precharge operation and the activate operation are to be performed on a first row of a first bank of the memory module and that the refresh operation is to be performed on the first bank of the memory module.

In a fifth aspect, in combination with one or more of the first aspect through the fourth aspect, a format of the merged command is a precharge command format.

In a sixth aspect, in combination with one or more of the first aspect through the fifth aspect, the merged command comprises an indication that the precharge operation is to be performed on a first row of a first bank of the memory module, that the refresh operation is to be performed on the first bank of the memory module, and that the activate operation is to be performed on the first row of the first bank of the memory module.

In a seventh aspect, in combination with one or more of the first aspect through the sixth aspect, the merged command comprises: a first indication that the precharge operation is to be performed on a first row of a first bank of the memory module and a second row, corresponding to the first row, of a second bank of the memory module, that the refresh operation is to be performed on the first bank and the second bank, and the activate operation is to be performed on the first row of the first bank of the memory module, wherein the first bank and the second bank belong to a bank pair; a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or a third indication that the precharge operation is to be performed on the first row of the first bank of the memory module and the second row of the second bank of the memory module, that the refresh operation is to be performed on the first bank and the second bank, and that the activate operation is to be performed on the first row of the first bank of the memory module and the second row of the second bank of the memory module.

In an eighth aspect, in combination with one or more of the first aspect through the seventh aspect, a format of the merged command is a refresh command format.

In a ninth aspect, in combination with one or more of the first aspect through the eighth aspect, the merged command comprises: a first indication that the precharge operation is to be performed on a first row of a first bank of the memory module and a second row, corresponding to the first row, of a second bank of the memory module, that the refresh operation is to be performed on the first bank and the second bank, and that the activate operation is to be performed on the first row of the first bank of the memory module, wherein the first bank and the second bank belong to a bank pair; a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or a third indication that the precharge operation is to be performed on the first row of the first bank and the second row of the second bank, that the refresh operation is to be performed on the first bank and the second bank, and that the activate operation is to be performed on the first row of the first bank and the second row of the second bank.

In a tenth aspect, supporting data operations may include an apparatus configured to perform operations comprising generating a merged command for performing at least a precharge operation, a refresh operation, and an activate operation on one or more rows of the memory module and transmitting the merged command to a memory module.

Additionally, the apparatus may perform or operate according to one or more aspects as described below. In some implementations, the apparatus includes a wireless device, such as a UE. In some implementations, the apparatus includes a remote server, such as a cloud-based computing solution, which receives image data for processing to determine output image frames. In some implementations, the apparatus may include at least one processor, and a memory coupled to the processor. The processor may be configured to perform operations described herein with respect to the apparatus. In some other implementations, the apparatus may include a non-transitory computer-readable medium having program code recorded thereon and the program code may be executable by a computer for causing the computer to perform operations described herein with reference to the apparatus. In some implementations, the apparatus may include one or more means configured to perform operations described herein. In some implementations, a method may include one or more operations described herein with reference to the apparatus. In some implementations, the apparatus may include a host device configured to communicate with a memory module through a channel. The host device may comprise a memory controller coupled to the channel and configured to perform or operate according to one or more of the aspects described herein.

In an eleventh aspect, in combination with the tenth aspect, the merged command is transmitted by the host device to the memory module via a command bus of the channel.

In a twelfth aspect, in combination with one or more of the tenth aspect through the eleventh aspect, a format of the merged command is a read command format or a write command format.

In a thirteenth aspect, in combination with one or more of the tenth aspect through the twelfth aspect, the merged command comprises an indication that the precharge operation and the activate operation are to be performed on a first row of a first bank of the memory module and that the refresh operation is to be performed on the first bank of the memory module.

In a fourteenth aspect, in combination with one or more of the tenth aspect through the thirteenth aspect, a format of the merged command is a precharge command format.

In a fifteenth aspect, in combination with one or more of the tenth aspect through the fourteenth aspect, the merged command comprises an indication that the precharge operation should be performed on a first row of a first bank of the memory module, that the refresh operation is to be performed on the first bank of the memory module, and that the activate operation is to be performed on the first row of the first bank of the memory module.

In a sixteenth aspect, in combination with one or more of the tenth aspect through the fifteenth aspect, the merged command comprises: a first indication that the precharge operation is to be performed on a first row of a first bank of the memory module and a second row, corresponding to the first row, of a second bank of the memory module, that the refresh operation is to be performed on the first bank and the second bank, and the activate operation is to be performed on the first row of the first bank of the memory module, wherein the first bank and the second bank belong to a bank pair; a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or a third indication that the precharge operation is to be performed on the first row of the first bank of the memory module and the second row of the second bank of the memory module, that the refresh operation is to be performed on the first bank and the second bank, and that the activate operation is to be performed on the first row of the first bank of the memory module and the second row of the second bank of the memory module.

In a seventeenth aspect, in combination with one or more of the tenth aspect through the sixteenth aspect, a format of the merged command is a refresh command format.

In an eighteenth aspect, in combination with one or more of the tenth aspect through the seventeenth aspect, a first indication that the precharge operation is to be performed on a first row of a first bank of the memory module and a second row, corresponding to the first row, of a second bank of the memory module, that the refresh operation is to be performed on the first bank and the second bank, and that the activate operation is to be performed on the first row of the first bank of the memory module, wherein the first bank and the second bank belong to a bank pair; a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or a third indication that the precharge operation is to be performed on the first row of the first bank and the second row of the second bank, that the refresh operation is to be performed on the first bank and the second bank, and that the activate operation is to be performed on the first row of the first bank and the second row of the second bank.

In the description of embodiments herein, numerous specific details are set forth, such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present disclosure. However, it will be apparent to one skilled in the art that these specific details may not be required to practice the teachings disclosed herein. In other instances, well known circuits and devices are shown in block diagram form to avoid obscuring teachings of the present disclosure.

Some portions of the detailed descriptions which follow are presented in terms of procedures, logic blocks, processing, and other symbolic representations of operations on data bits within a computer memory. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

In the figures, a single block may be described as performing a function or functions. The function or functions performed by that block may be performed in a single component or across multiple components, and/or may be performed using hardware, software, or a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example devices may include components other than those shown, including well-known components such as a processor, memory, and the like.

Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving,” “settling,” “generating,” or the like, refer to the actions and processes of a computer system, or similar electronic computing device, that manipulates and transforms data represented as physical (electronic) quantities within the computer system's registers and memories into other data similarly represented as physical quantities within the computer system's registers, memories, or other such information storage, transmission, or display devices.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (e.g., application specific integrated circuits (ASICs), digital signal processors (DSP), graphics processing unit (GPU), central processing unit (CPU)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-2 include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to the figures included with this description may be combined with one or more blocks (or operations) described with reference to another of the figures. For example, one or more blocks (or operations) of FIG. 3 may be combined with one or more blocks (or operations) of FIG. 1 or FIG. 2.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits, and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward” are sometimes used for ease of describing the figures, and indicate relative positions corresponding to the orientation of the figure on a properly oriented page, and may not reflect the proper orientation of any device as implemented.

As used herein, the term “coupled to” in the various tenses of the verb “couple” may mean that element A is directly connected to element B or that other elements may be connected between elements A and B (i.e., that element A is indirectly connected with element B), to operate certain intended functions. In the case of electrical components, the term “coupled to” may also be used herein to mean that a wire, trace, or other electrically conductive material is used to electrically connect elements A and B (and any components electrically connected therebetween). In some examples, the term “coupled to” mean a transfer of electrical energy between elements A and B, to operate certain intended functions.

In some examples, the term “electrically connected” mean having an electric current or configurable to having an electric current flowing between the elements A and B. For example, the elements A and B may be connected via resistors, transistors, or an inductor, in addition to a wire, trace, or other electrically conductive material and components. Furthermore, for radio frequency functions, the elements A and B may be “electrically connected” via a capacitor.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of′ what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An apparatus, comprising:
a memory controller coupled to a memory module through a first channel and configured to access data stored in the memory module through the first channel, and configured to perform operations comprising:
receiving, from a host device, a merged command for performing at least a precharge operation, a refresh operation, and an activate operation on one or more rows of the memory module; and
performing the precharge operation, the refresh operation, and the activate operation in accordance with receipt of the merged command.

2. The apparatus of claim 1, wherein:
the merged command is received by the memory controller from the host device via a command bus.

3. The apparatus of claim 1, wherein a format of the merged command is a read command format or a write command format.

4. The apparatus of claim 3, wherein the merged command comprises an indication that the precharge operation and the activate operation are to be performed on a first row of a first bank of the memory module and that the refresh operation is to be performed on the first bank of the memory module.

5. The apparatus of claim 1, wherein a format of the merged command is a precharge command format.

6. The apparatus of claim 5, wherein the merged command comprises an indication that the precharge operation is to be performed on a first row of a first bank of the memory module, that the refresh operation is to be performed on the first bank of the memory module, and that the activate operation is to be performed on the first row of the first bank of the memory module.

7. The apparatus of claim 5, wherein the merged command comprises:
a first indication that the precharge operation is to be performed on a first row of a first bank of the memory module and a second row, corresponding to the first row, of a second bank of the memory module, that the refresh operation is to be performed on the first bank and the second bank, and the activate operation is to be performed on the first row of the first bank of the memory module, wherein the first bank and the second bank belong to a bank pair;
a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or
a third indication that the precharge operation is to be performed on the first row of the first bank of the memory module and the second row of the second bank of the memory module, that the refresh operation is to be performed on the first bank and the second bank, and that the activate operation is to be performed on the first row of the first bank of the memory module and the second row of the second bank of the memory module.

8. The apparatus of claim 1, wherein a format of the merged command is a refresh command format.

9. The apparatus of claim 8, wherein the merged command comprises:
a first indication that the precharge operation is to be performed on a first row of a first bank of the memory module and a second row, corresponding to the first row, of a second bank of the memory module, that the refresh operation is to be performed on the first bank and the second bank, and that the activate operation is to be performed on the first row of the first bank of the memory module, wherein the first bank and the second bank belong to a bank pair;
a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or
a third indication that the precharge operation is to be performed on the first row of the first bank and the second row of the second bank, that the refresh operation is to be performed on the first bank and the second bank, and that the activate operation is to be performed on the first row of the first bank and the second row of the second bank.

10. A method, comprising:
receiving, from a host device by a memory controller coupled to a memory module through a first channel and configured to access data stored in the memory module through the first channel, a merged command for performing at least a precharge operation, a refresh operation, and an activate operation on one or more rows of the memory module; and
performing the precharge operation, the refresh operation, and the activate operation in accordance with receipt of the merged command.

11. The method of claim 10, wherein:
the merged command is received by the memory controller from the host device via a command bus.

12. The method of claim 10, wherein a format of the merged command is a read command format or a write command format.

13. The method of claim 12, wherein:
the merged command comprises an indication that the precharge operation and the activate operation are to be performed on a first row of a first bank of the memory module and that the refresh operation is to be performed on the first bank of the memory module.

14. The method of claim 10, wherein a format of the merged command is a precharge command format.

15. The method of claim 14, wherein the merged command comprises an indication that the precharge operation is to be performed on a first row of a first bank of the memory module, that the refresh operation is to be performed on the first bank of the memory module, and that the activate operation is to be performed on the first row of the first bank of the memory module.

16. The method of claim 14, wherein the merged command comprises:
a first indication that the precharge operation is to be performed on a first row of a first bank of the memory module and a second row, corresponding to the first row, of a second bank of the memory module, that the refresh operation is to be performed on the first bank and the second bank, and the activate operation is to be performed on the first row of the first bank of the memory module, wherein the first bank and the second bank belong to a bank pair;
a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or
a third indication that the precharge operation is to be performed on the first row of the first bank of the memory module and the second row of the second bank of the memory module, that the refresh operation is to be performed on the first bank and the second bank, and that the activate operation is to be performed on the first row of the first bank of the memory module and the second row of the second bank of the memory module.

17. The method of claim 10, wherein a format of the merged command is a refresh command format.

18. The method of claim 17, wherein the merged command comprises:
a first indication that the precharge operation is to be performed on a first row of a first bank of the memory module and a second row, corresponding to the first row, of a second bank of the memory module, that the refresh operation is to be performed on the first bank and the second bank, and that the activate operation is to be performed on the first row of the first bank of the memory module, wherein the first bank and the second bank belong to a bank pair;
a second indication that the precharge operation is to be performed on the first row of the first bank of the memory module and the second row of the second bank of the memory module, that the refresh operation is to be performed on the first bank and the second bank of the memory module, and that the activate operation is to be performed on the second row of the second bank of the memory module; or
a third indication that the precharge operation is to be performed on the first row of the first bank and the second row of the second bank, that the refresh operation is to be performed on the first bank and the second bank, and that the activate operation is to be performed on the first row of the first bank and the second row of the second bank.

19. An apparatus, comprising:
a host device configured to communicate with a memory module through a channel,
the host device comprising a memory controller coupled to the channel, the memory controller configured perform operations including:
generating a merged command for performing at least a precharge operation, a refresh operation, and an activate operation on one or more rows of the memory module; and
transmitting the merged command to the memory module.

20. The apparatus of claim 19, wherein:
the merged command is transmitted by the host device to the memory module via a command bus of the channel.

21. The apparatus of claim 19, wherein a format of the merged command is a read command format or a write command format.

22. The apparatus of claim 21, wherein:
the merged command comprises an indication that the precharge operation and the activate operation are to be performed on a first row of a first bank of the memory module and that the refresh operation is to be performed on the first bank of the memory module.

23. The apparatus of claim 19, wherein a format of the merged command is a precharge command format.

24. The apparatus of claim 19, wherein a format of the merged command is a refresh command format.

25. A method, comprising:
generating, by a host device configured to communicate with a memory module via a channel, a merged command for performing at least a precharge operation, a refresh operation, and an activate operation on one or more rows of the memory module; and
transmitting the merged command to the memory module.

26. The method of claim 25, wherein:
the merged command is transmitted by the host device to the memory module via a command bus of the channel.

27. The method of claim 25, wherein a format of the merged command is a read command format or a write command format.

28. The method of claim 25, wherein:
the merged command comprises an indication that the precharge operation and the activate operation are to be performed on a first row of a first bank of the memory module and that the refresh operation is to be performed on the first bank of the memory module.

29. The method of claim 25, wherein a format of the merged command is a precharge command format.

30. The method of claim 25, wherein a format of the merged command is a refresh command format.
